(19) United States
(12) Patent Application Publication
(10) Pub. No.: US 2026/0162729 A1
(43) Pub. Date: Jun. 11, 2026

(54) MEMORY DEVICE AND DATA ERASING METHOD THEREOF

(71) Applicant: Winbond Electronics Corp., Taichung City (TW)

(72) Inventors: Ju-Chieh Cheng, Taichung City (TW); Yu-Cheng Chuang, Hsinchu County (TW); Shan-Hsuan Tsai, Taichung City (TW); Liang-Cheng Shih, Taichung City (TW)

(73) Assignee: Winbond Electronics Corp., Taichung City (TW)

(21) Appl. No.: 19/366,495

(22) Filed: Oct. 22, 2025

(30) Foreign Application Priority Data
Dec. 10, 2024 (TW) 113147808

(51) Int. Cl. G11C 16/14; G11C 16/04; G11C 16/08; G11C 16/34

(52) U.S. Cl. CPC G11C 16/14; G11C 16/0483; G11C 16/08; G11C 16/3445

(57) ABSTRACT

A memory device and a data erasing method are provided. The data erasing method includes: dividing a memory block into a plurality of memory cell divisions; performing a first data erasing operation on the memory cell divisions; starting from a first memory cell division, performing a first erasing verification operation on each of the memory cell divisions one by one according to a first sequence and recording a first failure memory cell division; starting from a N^{th} memory cell division, performing a second erasing verification operation on each of the memory cell divisions one by one according to a second sequence and recording a second failure memory cell division; and performing a second data erasing operation on at least one selected memory cell division between the first failure memory cell division and the second failure memory cell division.

### CROSS-REFERENCE TO RELATED APPLICATION

This application claims the priority benefit of Taiwan application serial no. 113147808, filed on December 10, 2024. The entirety of the above-mentioned patent application is hereby incorporated by reference herein and made a part of this specification.

### BACKGROUND

### TECHNICAL FIELD

The disclosure relates to a memory device and a data erasing method thereof, and particularly relates to a memory device capable of enhancing a service life and a data erasing method thereof.

### DESCRIPTION OF RELATED ART

Generally, conventional NOR flash memory performs data erasing operations in the form of blocks. Due to factors such as process uniformity or defects, there may be a phenomenon known as tailing or outlier slow erasing memory cells. However, when performing a data erasing operation, the current method is to erase an entire memory block, and the erasing operation cannot be performed individually for the slow erasing memory cells. Therefore, after a long period of continuously performing writing and applying an erasing voltage, in order to complete the erasure of the slow erasing memory cells, degradation of normal memory cells is accelerated.

### SUMMARY

The disclosure is directed to a memory device and a data erasing method thereof capable of reducing the number of erasing operations required by the memory device and increasing its service life.

The data erasing method of the disclosure includes the following steps. A memory block is divided into a plurality of memory cell divisions, where each of the memory cell divisions includes at least one word line. A first data erasing operation is performed on the memory cell divisions of the memory block. Starting from a first memory cell division in the memory cell divisions, a first erasing verification operation is performed on each of the memory cell divisions one by one according to a first sequence, and a first failure memory cell division of a memory cell is recorded, where a first verification failure occurs in the first erasing verification operation. Starting from an N^{th} memory cell division in the memory cell divisions, a second erasing verification operation is performed on each of the memory cell divisions one by one according to a second sequence, and a second failure memory cell division of a memory cell is recorded, where the first verification failure occurs in the second erasing verification operation, and N is greater than 1. A second data erasing operation is performed on at least one selected memory cell division between the first failure memory cell division and the second failure memory cell division.

The disclosure provides a memory device including a memory block and a controller. The memory block is divided into a plurality of memory cell divisions, and each memory cell division includes at least one word line. The controller is coupled to the memory block. The controller is configured to execute the above data erasing method.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a flow chart of a data erasing method of a memory device according to an embodiment of the disclosure.

FIG. 2 is a flow chart of a data erasing method of a memory device according to another embodiment of the disclosure.

FIG. 3 is an operational schematic diagram of a data erasing method of a memory device according to an embodiment of the disclosure.

FIG. 4 is an operational schematic diagram of a data erasing method of a memory device according to an embodiment of the disclosure.

FIG. 5A is a schematic diagram of a masking operation of a memory cell according to an embodiment of the disclosure.

FIG. 5B is a schematic diagram of an erasing operation of a memory cell according to an embodiment of the disclosure.

FIG. 6 is a schematic diagram of a memory device according to an embodiment of the disclosure.

### DESCRIPTION OF THE E MBODIMENTS

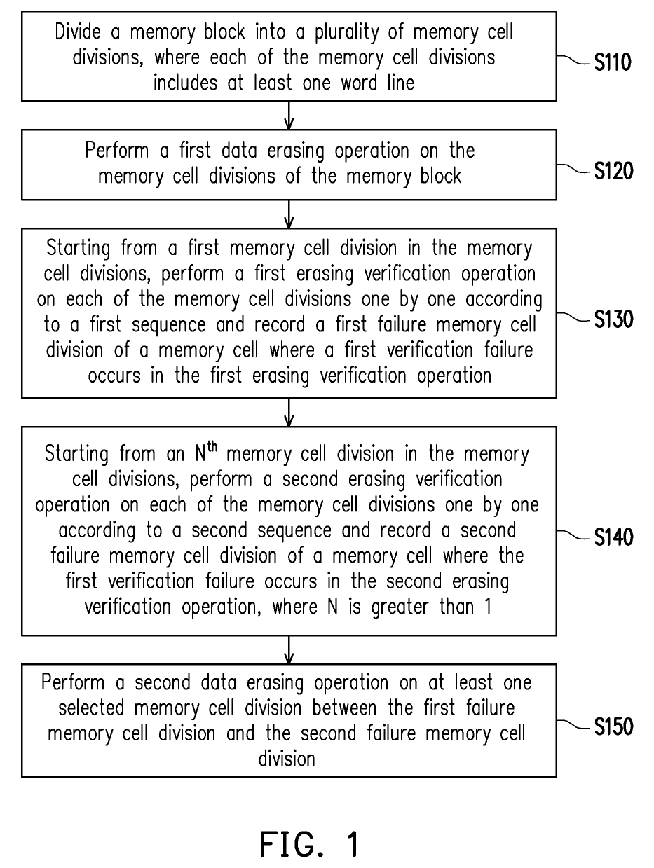

Referring to FIG. 1, FIG. 1 is a flow chart of a data erasing method of a memory device according to an embodiment of the disclosure. In the data erasing method of the memory device, in step S110, the memory device divides a memory block into a plurality of memory cell divisions, where each memory cell division includes one or a plurality of word lines. In step S120, the memory device performs a first data erasing operation on the plurality of memory cell divisions of the memory block. The first data erasing operation of all of the memory cell divisions of the memory block may be executed simultaneously.

In step S130, starting from a first memory cell division in the plurality of memory cell divisions, the memory device performs a first erasing verification operation on each of the memory cell divisions one by one according to a first sequence. The memory device records a first failure memory cell division of a memory cell where a first verification failure occurs in the first erasing verification operation. The memory device may first perform the first erasing verification operation on the first memory cell division, and then the memory device may perform the first erasing verification operation on a second memory cell division. The memory device may perform the first erasing verification operations one by one according to the sequence of the plurality of memory cell divisions. Furthermore, during the execution of the first erasing verification operation, when a memory cell that fails the verification for the first time occurs, the memory device may stop executing the first erasing verification operation and record address information of the first failure memory cell division corresponding to the failed memory cell.

Moreover, in step S140, starting from an N^{th} memory cell division in the memory cell divisions (where N is a positive greater than 1), the memory device performs a second erasing verification operation on each of the memory cell divisions one by one according to a second sequence. The memory device records a second failure memory cell division of a memory cell where the first verification failure occurs in the second erasing verification operation.

In detail, the N^{th} memory cell division may be a memory cell division arranged at a later segment in the memory cell divisions, for example, the last memory cell division. The memory device may perform the second erasing verification operation on each of the memory cell divisions one by one according to the second sequence that is opposite to the first sequence. For example, the memory device may first perform the second erasing verification operation on the N^{th} memory cell division, and then the memory device may perform the second erasing verification operation on an (N-1)^{th} memory cell division, and the rest may be deduced by analogy.

In the second erasing verification operation performed by the memory device, when a memory cell that fails the first verification occurs, the memory device may stop the second erasing verification operation, and record address information of the second failure memory cell division corresponding to the failed memory cell.

In step S150, the memory device performing a second data erasing operation on at least one selected memory cell division between the first failure memory cell division and the second failure memory cell division. The memory device may perform the second data erasing operation on the first failure memory cell division, the second failure memory cell division, and the memory cell divisions between the first failure memory cell division and the second failure memory cell division.

In detail, in each of the above data erasing operations, the memory device may provide a mask voltage to the word lines of the unselected memory cell divisions outside the selected memory cell divisions through the controller, and provide an erasing voltage to the word lines of the selected memory cell divisions. In this way, the controller may perform a block-type data erasing operation (second data erasing operation) for the selected memory cell division. While the second data erasing operation is executed, the word lines based on the unselected memory cell divisions receive the mask voltage, so that memory cells in the unselected memory cell divisions may be masked without being affected by the erasing voltage, and maintain an original state.

In the embodiment, an absolute value of a voltage difference between the mask voltage and a bulk voltage of the memory block is less than an absolute value of a voltage difference between the erasing voltage and the bulk voltage of the memory block. Based on the voltage difference generated between the bulk voltage of the memory block and the erasing voltage, charges stored in the memory cells may be effectively removed to achieve the data erasing operation. In contrast, a difference between the bulk voltage and the mask voltage of the memory block is not enough to remove the charge stored in the memory cell, and therefore, the corresponding memory cell may be effectively masked during the second data erasing operation.

It should be noted that after the second data erasing operation, the memory device may make one or a plurality of memory cell divisions between the first failure memory cell division and the second failure memory cell division to become a new memory cell block, and perform steps S130 to S150 on this new memory cell block. The above operations may be executed repeatedly until all memory cells pass the erasing verification operation, or the number of the data erasing operations is greater than a preset threshold.

In the embodiment of the disclosure, in the data erasing operation of the memory block, the memory cells on the memory cell division that pass the erasing verification may have a mask to avoid being affected by a bias voltage between the erasing voltage and the bulk voltage during the second data erasing operation, which may effectively slow down a degradation rate of the memory cells, thereby increasing an overall service life of the memory device.

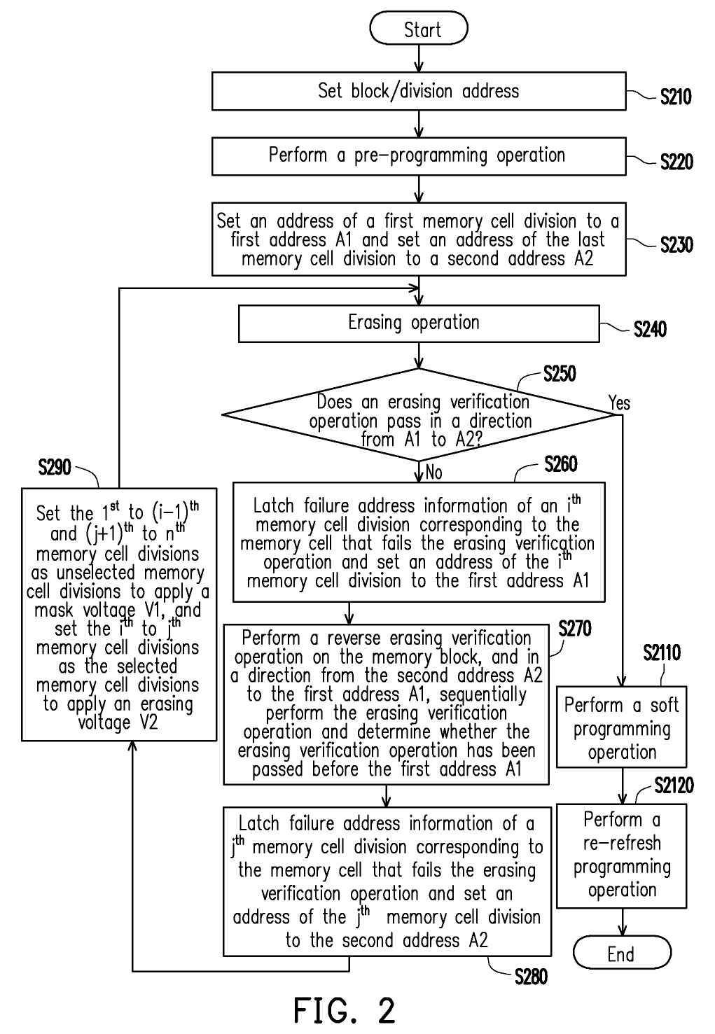

Referring to FIG. 2, FIG. 2 is a flow chart of a data erasing method of a memory device according to another embodiment of the disclosure. In step S210, the controller of the memory device may perform address setting on a memory block and a plurality of memory cell divisions in the memory device. In step S220, the controller may perform a pre-programming operation on the memory block. In step S230, the controller may perform an initialization operation, set an address of the first memory cell division to a first address A1 (A1=1), and set an address of the last (n^{th}) memory cell division to a second address A2 (A2=n).

In step S240, the controller may perform an erasing operation on all of the memory cell divisions in the memory block. In step S250, the controller may perform an erasing verification operation on the memory block and sequentially perform the erasing verification operation from the first address A1 to the second address A2, so as the determine whether the erasing verification operation is passed. When the erasing verification operation is failed, step S260 may be executed. On the other hand, if the erasing verificaion operations of the memory cell divisions from the first address A1 to the second address A2 are all passed, step S2110 may be executed.

In step S2110, the controller may perform a soft programming operation on the memory block. The controller may prevent excessive erasure of the memory cells in the memory device through the soft programming operation. Next, in step S2120, the controller may perform a re-refresh programming operation on the memory block.

In step S260, the controller may latch failure address information of an i^{th} memory cell division corresponding to the memory cell that fails the erasing verification operation in step S250, and may set an address of the i^{th} memory cell division to the first address A1 (A1=i).

In step S270, the controller may perform a reverse erasing verification operation on the memory block, where in a direction from the second address A2 to the first address A1, the controller sequentially performs the erasing verification operation, and determines whether the erasing verification operation has been passed before the first address A1.

In step S280, the controller may latch failure address information of a j^{th} memory cell division corresponding to the memory cell that fails the erasing verification operation in step S270, and may set an address of the j^{th} memory cell division to the second address A2 (A2=j), where i and j may be the same or different.

In step S290, the controller may set the 1^{st} to (i-1)^{th} and (j+1)^{th} to n^{th} memory cell divisions as unselected memory cell divisions, and apply a mask voltage V1 to word lines of the 1^{st} to (i-1)^{th} and (j+1)^{th} to n^{th} memory cell divisions. The controller may also set the i^{th} to j^{th} memory cell divisions as the selected memory cell divisions, and apply an erasing voltage V2 to the word lines of the i^{th} to j^{th} memory cell divisions. After step S290, the controller may re-execute step S240.

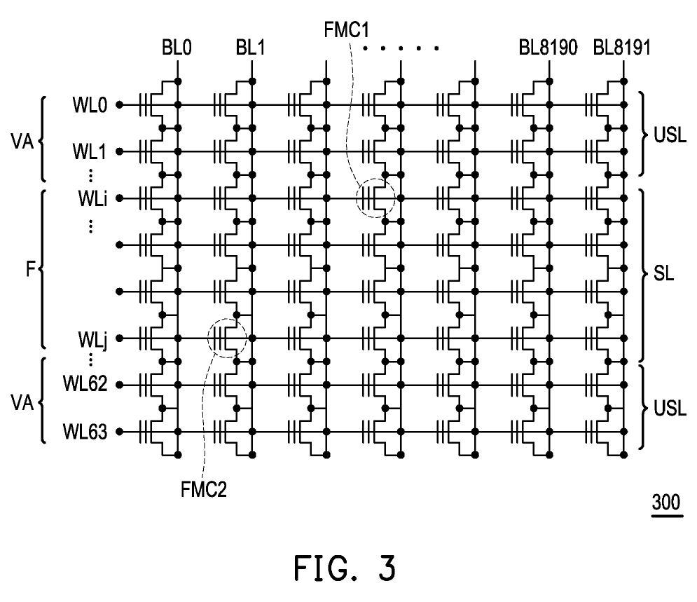

Referring to FIG. 3, FIG. 3 is an operational schematic diagram of a data erasing method of a memory device according to an embodiment of the disclosure. In FIG. 3, a memory block 300 is a NOR flash memory block. The memory block 300 has a plurality of word lines WL0-WL63 and a plurality of bit lines BL0-BL8191. Each of the word lines WL0-WL63 may be provided with a plurality of flash memory cells. In the embodiment, the memory block 300 may be divided into 64 memory cell divisions corresponding to the word lines WL0-WL63. Namely, in the embodiment, each memory cell division has only one word line. After the first data erasing operation is completed, the controller may take the memory cell on the word line WL0 and the bit line BL0 as a start point to perform the first erasing verification operation on each of the memory cells in directions toward the bit line BL8191 and the word line WL63. In the embodiment, the controller verifies that a memory cell FMC1 on the word line WLi is a failure memory cell that first fails the verification through the first erasing verification operation. The controller may record the address information of the word line WLi.

Next, the controller may take the memory cell on the word line WL63 and the bit line BL8191 as a start point to perform the second erasing verification operation on each of the memory cells in directions toward the bit line BL0 and the word line WL0. In the embodiment, the controller verifies that a memory cell FMC2 on the word line WLj is a failure memory cell that first fails the verification through the second erasing verification operation. The controller may record the address information of the word line WLj.

Further, the controller may set a memory cell division of the word lines WLi to WLj as a verification failure division F, and set other memory cell divisions as a verification-passing divisions VA. Correspondingly, the controller may set the verification failure division F as a selected memory cell division SL, and set the verification-passing divisions VA as unselected memory cell divisions USL. Further, the controller may apply the mask voltage to the word lines of the unselected memory cell divisions USL, and apply the erasing voltage to the word lines of the selected memory cell division SL, so as to perform another data erasing operation on the memory cells of the selected memory cell division SL.

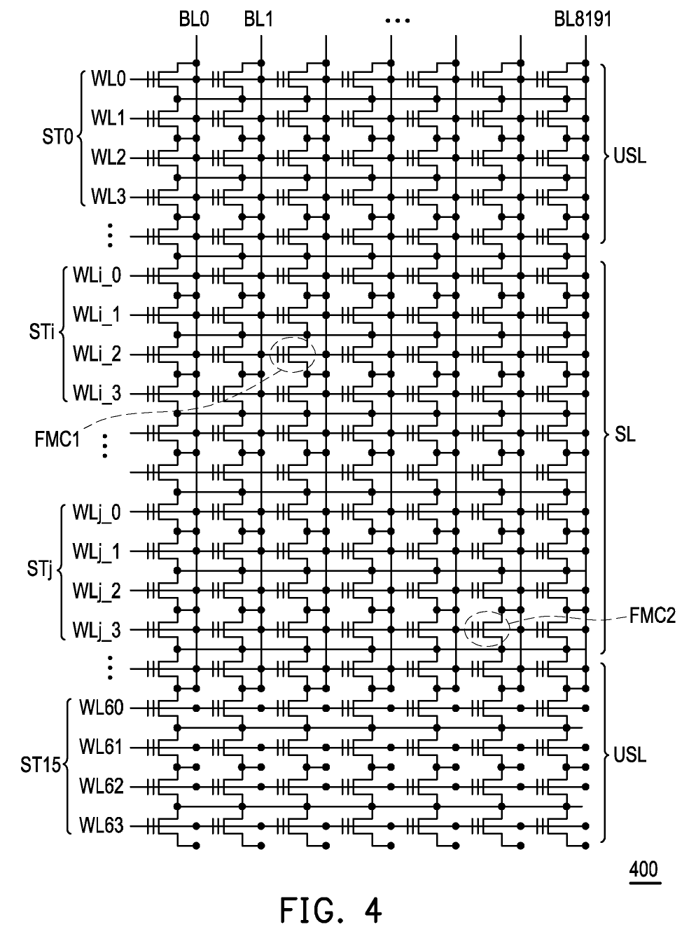

Referring to FIG. 4, FIG. 4 is an operational schematic diagram of a data erasing method of a memory device according to an embodiment of the disclosure. In FIG. 4, a memory block 400 is an NOR flash memory block. The memory block 400 has a plurality of word lines WL0-WL63 and a plurality of bit lines BL0-BL8191. Each of the word lines WL0-WL63 may be provided with a plurality of flash memory cells. In the embodiment, the memory block 400 may be divided into 16 memory cell divisions ST0-ST15, where one memory cell division has, for example, four word lines.

Certainly, in other embodiments of the disclosure, the number of word lines in one memory cell division may be planned by a designer without any restriction.

In the embodiment, after the first data erasing operation is completed, the controller may take the memory cell on the word line WL0 and the bit line BL0 as a start point to perform the first erasing verification operation on each of the memory cells in directions toward the bit line BL8191 and the word line WL63. In the embodiment, the controller verifies that a memory cell FMC1 on a word line WLi_2 is a failure memory cell that first fails the verification through the first erasing verification operation. The controller may record the address information of the memory cell division STi corresponding to the word line WLi_2.

Then, the controller may take the memory cell on the word line WL63 and the bit line BL8191 as a start point to perform the second erasing verification operation on each of the memory cells in directions toward the bit line BL0 and the word line WLi_0. In the embodiment, the controller verifies that a memory cell FMC2 on the word line WLj_3 is a failure memory cell that first fails the verification through the second erasing verification operation. The controller may record the address information of the memory cell division STj corresponding to the word line WLj_3.

Further, the controller may set the memory cell divisions STi to STj as a selected memory cell division SL, and set the other memory cell divisions VA as unselected memory cell divisions USL. The controller may apply the mask voltage to the word lines of the unselected memory cell divisions USL, and apply the erasing voltage to the word lines of the selected memory cell division SL, so as to perform another data erasing operation on the memory cells of the selected memory cell division SL.

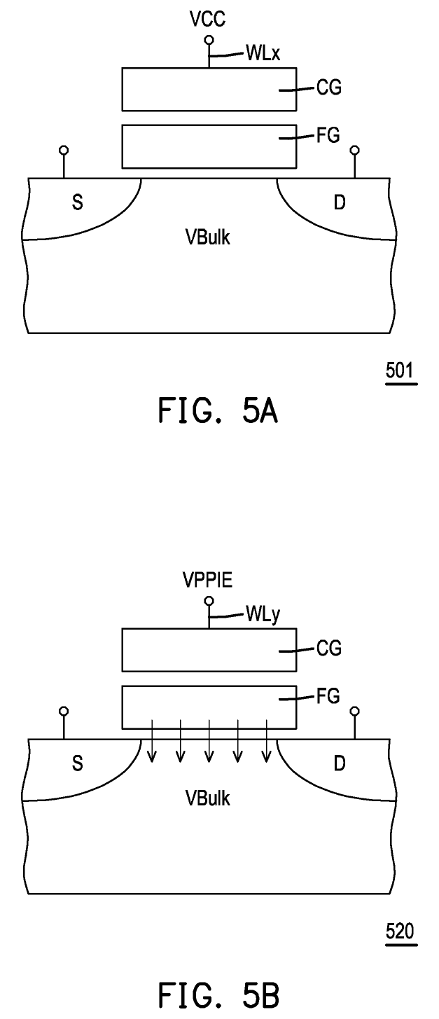

FIG. 5A is a schematic diagram of a masking operation of a memory cell according to an embodiment of the disclosure. Referring to FIG. 5A, a memory cell 501 has a floating gate FG and a control gate CG. When the memory cell 501 corresponds to an unselected word line WLx, the control gate CG coupled to the word line WLx may receive a mask voltage VCC, a bulk terminal of the memory cell 501 may receive a bulk voltage VBulk, and a source S and a drain D of the memory cell 501 may be in a floating state. In the embodiment, the mask voltage VCC and the bulk voltage VBulk may both be positive voltages. For example, the mask voltage VCC may be 2V, and the bulk voltage VBulk may be 10V.

FIG. 5B is a schematic diagram of an erasing operation of a memory cell according to an embodiment of the disclosure. Referring to FIG. 5B, a memory cell 520 also has a floating gate FG and a control gate CG. When the memory cell 520 corresponds to a selected word line WLy, the control gate CG coupled to the word line WLy may receive an erasing voltage VPPIE, a bulk terminal of the memory cell 520 may also receive a bulk voltage VBulk, and a source S and a drain D of the memory cell 520 may be in a floating state. In the embodiment, the erasing voltage VPPIE may be a negative voltage, and the bulk voltage VBulk may be a positive voltage, for example, the erasing voltage VPPIE may be -10V, and the bulk voltage VBulk may be 10V.

According to the description of FIG. 5A and FIG. 5B, it may be known that when performing the second data erasing operation, an absolute value (=8V) of a voltage difference between the bulk voltage VBulk of the memory cell corresponding to the unselected word line WLx and the mask voltage received by the word line WLx may be less than an absolute value (=20V) of a voltage difference between the bulk voltage VBulk of the memory cell corresponding to the unselected word line WLy and the erasing voltage VPPIE received by the word line WLy.

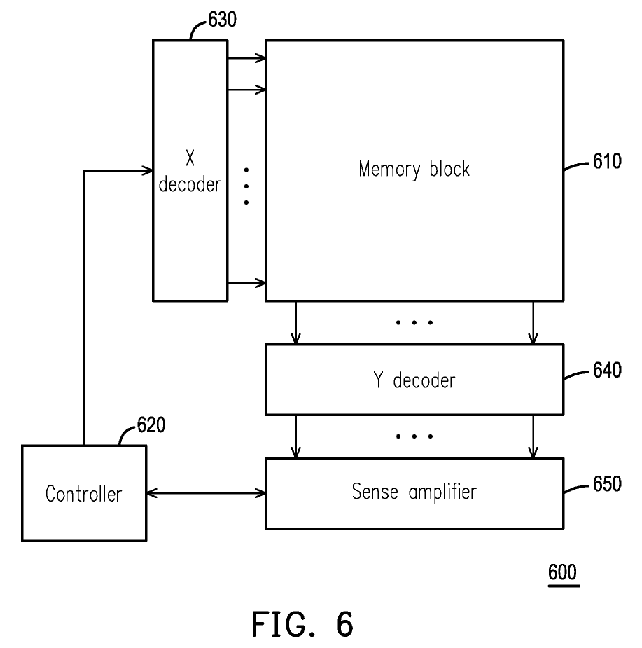

Referring to FIG. 6 below, FIG. 6 is a schematic diagram of a memory device according to an embodiment of the disclosure. The memory device 600 includes a memory block 610, a controller 620, an X decoder 630, a Y decoder 640, and a sense amplifier 650. The memory block 610 is coupled to X decoder 630 and the Y decoder 640. The Y decoder 640 is further coupled to the sense amplifier 650. The controller 620 may be coupled to the X decoder 630, the Y decoder 640, and the sense amplifier 650.

The X decoder 630 is configured to generate X-direction address information of the memory block 610, i.e., a word line signal of the memory block 610. The Y decoder 640 is configured to generate Y-direction address information of the memory block 610, i.e., a bit line signal of the memory block 610. The sense amplifier 650 is configured to sense a read signal of the memory block 610. In the embodiment, during the erasing verification operation, the sense amplifier 650 may can learn whether each memory cell is in an erased state by sensing a threshold voltage of each memory cell.

The controller 620 is configured to execute the data erasing method in FIG. 1 and FIG. 2, and the relevant details have been described in detail in the foregoing embodiments, which will not be repeated.

In the embodiment, the X decoder 630, the Y decoder 640 and the sense amplifier 650 may be implemented by relevant circuits well known to those of ordinary skill in the art. The controller 620 may be a processor with computing capabilities. Alternatively, the controller 620 may be implemented through a hardware description language or other digital circuit design methods well known to those skilled in the art, and may be a hardware circuit implemented in the form of a field programmable logic gate array, a complex programmable logic device, or an application specific integrated circuit. The memory block 410 may be an NOR flash memory block.

In view of the foregoing, in the data erasing method of the memory device of the disclosure, when the erasing verification operation fails, before performing the next data erasing operation, a bidirectional erasing verification method is used to set the memory cell division that has passed the erasing verification as the unselected memory cell division, and set the memory cell division that has not passed the erasing verification as the selected memory cell division. When performing the next data erasure operation, the unselected memory cell divisions may be masked and the data erasing operation may only be performed on the memory cells of the selected memory cell division. In this way, the memory cells that have passed the erasing verification will not be applied with the erasing bias for multiple times, which may reduce a rate of memory cell degradation and extend a service life of the memory device.

What is claimed is:

1. A data erasing method, comprising:
dividing a memory block into a plurality of memory cell divisions, wherein each of the memory cell divisions comprises at least one word line;
performing a first data erasing operation on the memory cell divisions of the memory block,
starting from a first memory cell division in the memory cell divisions, performing a first erasing verification operation on each of the memory cell divisions one by one according to a first sequence, and recording a first failure memory cell division of a memory cell where a first verification failure occurs in the first erasing verification operation;
starting from an N^{th} memory cell division in the memory cell divisions, performing a second erasing verification operation on each of the memory cell divisions one by one according to a second sequence, and recording a second failure memory cell division of a memory cell where the first verification failure occurs in the second erasing verification operation, wherein N is a positive integer greater than 1; and
performing a second data erasing operation on at least one selected memory cell division between the first failure memory cell division and the second failure memory cell division.

2. The data erasing method according to claim 1, wherein the first sequence and the second sequence are reversed.

3. The data erasing method according to claim 1, wherein the N^{th} memory cell division is the last memory cell division.

4. The data erasing method according to claim 1, wherein the step of performing the second data erasing operation on the at least one selected memory cell division between the first failure memory cell division and the second failure memory cell division comprises:
providing a mask voltage to at least one first word line of at least one unselected memory cell division outside the at least one selected memory cell division to mask the at least one unselected memory cell division; and
providing an erasing voltage to at least one second word line of the at least one selected memory cell division to perform the second data erasing operation on a plurality of memory cells in the at least one selected memory cell division.

5. The data erasing method according to claim 4, wherein an absolute value of a voltage difference between the mask voltage and a bulk voltage of the memory block is less than an absolute value of a voltage difference between the erasing voltage and the bulk voltage of the memory block.

6. The data erasing method according to claim 5, wherein the bulk voltage of the memory block and the mask voltage are positive voltages, and the erasing voltage is a negative voltage.

7. The data erasing method according to claim 1, further comprising:
recording first address information of the first failure memory cell division and second address information of the second failure memory cell division.

8. The data erasing method according to claim 7, further comprising:
setting the at least one memory cell division corresponding to the first address information to the second address information as the at least one selected memory cell division.

9. The data erasing method according to claim 1, wherein before the first data erasing operation, the data erasing method further comprises:
performing a pre-programming operation on the memory block.

10. The data erasing method according to claim 1, further comprising:
after the second data erasing operation, performing a second erasing verification operation; and
when a verification result of the second erasing verification operation is a pass, sequentially performing a soft programming operation and a re-refresh programming operation.

11. A memory device, comprising:
a memory block, divided into a plurality of memory cell divisions, and each of the memory cell divisions comprising at least one word line; and
a controller, coupled to the memory block, and the controller being configured to:
perform a first data erasing operation on the memory cell divisions of the memory block;
starting from a first memory cell division in the memory cell divisions, perform a first erasing verification operation on each of the memory cell divisions one by one according to a first sequence and record a first failure memory cell division of a memory cell where a first verification failure occurs in the first erasing verification operation;
starting from an N^{th} memory cell division in the memory cell divisions, perform a second erasing verification operation on each of the memory cell divisions one by one according to a second sequence and record a second failure memory cell division of a memory cell where the first verification failure occurs in the second erasing verification operation, wherein N is a positive integer greater than 1; and
perform a second data erasing operation on at least one selected memory cell division between the first failure memory cell division and the second failure memory cell division.

12. The memory device according to claim 11, wherein the first sequence and the second sequence are reversed.

13. The memory device according to claim 11, wherein the N^{th} memory cell division is the last memory cell division.

14. The memory device according to claim 11, wherein the controller is configured to:
provide a mask voltage to at least one first word line of at least one unselected memory cell division outside the at least one selected memory cell division to mask the at least one unselected memory cell division; and
provide an erasing voltage to at least one second word line of the at least one selected memory cell division to perform the second data erasing operation on a plurality of memory cells in the at least one selected memory cell division.

15. The memory device according to claim 14, wherein an absolute value of a voltage difference between the mask voltage and a bulk voltage of the memory block is less than an absolute value of a voltage difference between the erasing voltage and the bulk voltage of the memory block.

16. The memory device according to claim 15, wherein the bulk voltage of the memory block and the mask voltage are positive voltages, and the erasing voltage is a negative voltage.

17. The memory device according to claim 11, wherein the controller is configured to:
record first address information of the first failure memory cell division and second address information of the second failure memory cell division.

18. The memory device according to claim 17, wherein the controller is configured to:
set the at least one memory cell division corresponding to the first address information to the second address information as the at least one selected memory cell division.

19. The memory device according to claim 11, wherein the controller is configured to:
perform a pre-programming operation on the memory block before the first data erasing operation.

20. The memory device according to claim 11, wherein the controller is configured to:
after the second data erasing operation, perform a second erasing verification operation; and
when a verification result of the second erasing verification operation is a pass, sequentially perform a soft programming operation and a re-refresh programming operation.
